(19) United States
(12) Patent Application Publication
(10) Pub. No.: US 2007/0158811 A1
(43) Pub. Date: Jul. 12, 2007

(54) Low profile managed memory component

(76) Inventors: James Douglas Wehrly, Austin, TX (US); Leland Szewerenko, Austin, TX (US); Bert Haskell, Austin, TX (US)

Correspondence Address: FISH & RICHARDSON P.C., P.O BOX 1022, Minneapolis, MN, 55440-1022, US

(21) Appl. No.: 11/502,852

(22) Filed: Aug. 11, 2006

Related U.S. Application Data
(63) Continuation-in-part of application No. 11/330,307, filed on Jan. 11, 2006.
Application No. 11/330,307 is a continuation-in-part of application No. 11/436,946, filed on May 18, 2006.

(51) Int. Cl. H01L 23/02

(52) U.S. Cl. 257/686

(57) ABSTRACT

A system and method for combining at least two semiconductor die using multi-layer flex circuitry is provided. A first semiconductor die is attached and preferably electrically connected to a first layer of the flex circuitry while a second semiconductor die is set, at least in part, into a window that extends into the flex circuitry to expose a layer of the flex to which the second die is attached. When the second semiconductor die is a flip-chip device, it is connected through its contacts to the layer of flex exposed in the window and when it is a die with its contact side oriented away from the flex circuitry, it is preferably electrically connected with wire bonds to another conductive layer of the flex circuitry. In preferred modules, the first semiconductor die is preferably a flash memory circuit and the second semiconductor die is preferably a controller.

### RELATED APPLICATIONS

The present application is a continuation-in-part of U.S. patent application Ser. No. 11/330,307, filed Jan. 11, 2006, pending, and a continuation-in-part of U.S. patent application Ser. No. 11/436,946, filed May 18, 2006, pending.

### TECHNICAL FIELD

This invention relates to integrated circuit modules and, in particular, to integrated circuit modules that provide memory and controller in a compact footprint module.

### BACKGROUND

A variety of systems and techniques are known for combining integrated circuits in compact modules. Some techniques are suitable for combining packaged integrated circuits and others are suitable for combining semiconductor die. Many systems and techniques employ flex circuitry as a connector between packaged integrated circuits in, for example, stacks of packaged leaded or chip-scale integrated circuits. Other techniques employ flex circuitry to “package” semiconductor die and function as a substitute for packaging.

Within the group of technologies that stack packaged integrated circuits, some techniques are devised for stacking chip-scale packaged devices (CSPs) while other systems and methods are better directed to leaded packages such as those that exhibit a set of leads extending from at least one lateral side of a typically rectangular package.

Integrated circuit devices (ICs) are packaged in both chip-scale (CSP) and leaded packages. However, techniques for stacking CSP devices are typically not optimum for stacking leaded devices, just as techniques for leaded device stacking are typically not suitable for CSP devices.

Although CSP devices are gaining market share, in many areas, integrated circuits continue to be packaged in high volumes in leaded packages. For example, the well-known flash memory integrated circuit is typically packaged in a leaded package with fine-pitched leads emergent from one or both sides of the package. A common package for flash memory is the thin small outline package commonly known as the TSOP typified by leads emergent from one or more (typically a pair of opposite sides) lateral sides of the package.

Flash memory devices are gaining wide use in a variety of applications. Typically employed with a controller for protocol adaption, flash memory is employed in solid state memory storage applications that are supplanting disk drive technologies.

Two principal techniques are typically employed to combine flash memory circuitry with a controller circuit. The two integrated circuits are disposed roughly along the same lateral plane or they are vertically stacked in a module. The present assignee has developed several modules that aggregate flash memory with controller circuitry through stacking.

Some applications cannot, however, accommodate the greater height implicit in stacking flash memory with controller circuitry. This is particularly true when the flash memory in such modules is packaged as a TSOP. Consequently, what is needed is a compact and thin circuit module amenable to flash module implementation that exhibits a profile commensurate with the needs of more demanding applications.

### SUMMARY OF THE INVENTION

The present invention provides a system and method for combining at least two semiconductor die using multi-layer flex circuitry. A first semiconductor die is attached and preferably electrically connected to a first layer of the flex circuitry while a second semiconductor die is set, at least in part, into a window that extends into the flex circuitry to expose a layer of the flex to which the second die is attached. When the second semiconductor die is a flip-chip device, it is connected through its contacts to the layer of flex exposed in the window and when it is a die with its contact side oriented away from the flex circuitry, the second die is preferably electrically connected with wire bonds to another conductive layer of the flex circuitry. In preferred modules, the first semiconductor die is preferably a flash memory circuit and the second semiconductor die is preferably a controller.

### BRIEF DESCRIPTION OF THE DRAWINGS

FIG. 1 is a cross-sectional view of an exemplar module devised in accordance with a preferred embodiment of the present invention.

FIG. 2 is an enlarged cross-sectional view of the approximate area marked “A” in FIG. 1.

FIG. 3 is an enlarged cross-sectional view of an exemplar flex circuitry in accordance with a preferred embodiment of the present invention.

FIG. 4 depicts a cross-sectional view of an alternative embodiment in accordance with the present invention.

FIG. 5 is an enlarged cross-sectional depiction of an embodiment in which two semiconductor die are flip-chip devices with contact faces disposed in opposite directions and toward each other.

FIG. 6 illustrates an embodiment in accordance with the present invention in which one semiconductor die is a flip-chip device and a second semiconductor die is connected to the flex circuitry with wire bonds and the respective contact faces of the die are oriented in the same direction.

### DETAILED DESCRIPTION

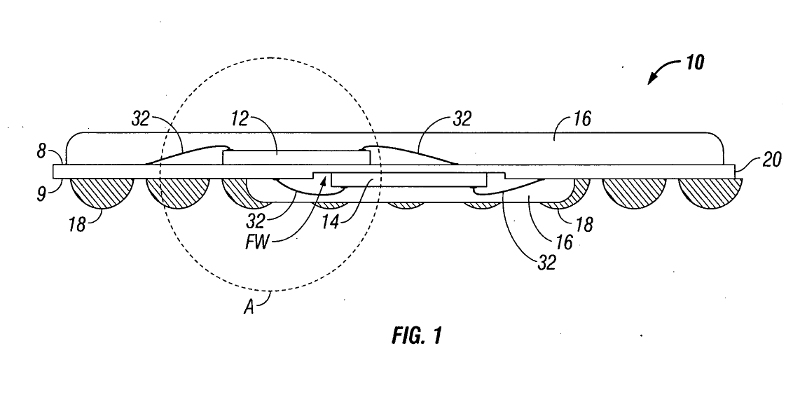

FIG. 1 is a cross-sectional view of an exemplar circuit module 10 devised in accordance with a preferred embodiment of the present invention. Exemplar module 10 is comprised of two semiconductor die 12 and 14, each connected to flex circuitry 20. In preferred embodiments, semiconductor die 12 is a flash memory device and semiconductor die 14 is a controller.

Semiconductor die 12 is disposed on side 8 of flex circuitry 20 while semiconductor die 14 is disposed at least in part, into a window FW that is set into side 9 of the flex circuitry. In a preferred embodiment, semiconductor die 12 and 14 are covered by an encapsulate 16 as shown. Module contacts 18 are shown arrayed along side 9 of flex circuitry 20.

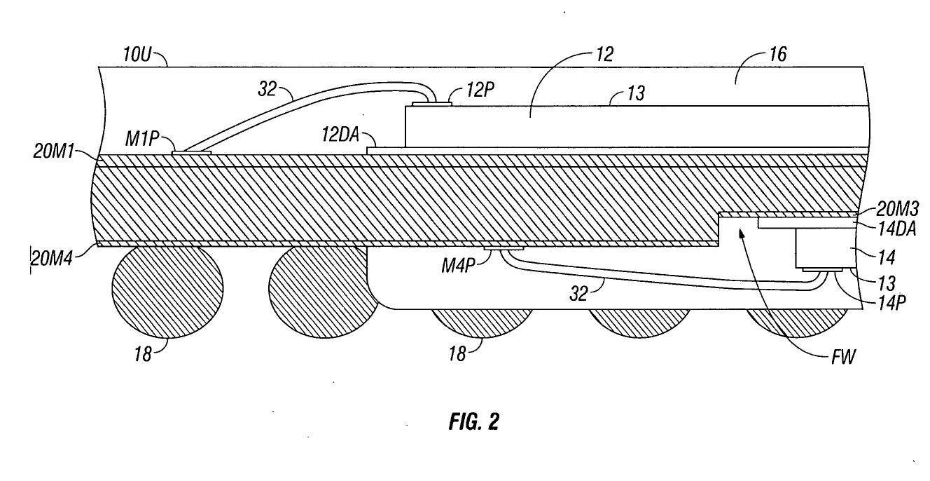

FIG. 2 is an enlarged cross-sectional view of the approximate area marked “A” in FIG. 1. As shown in FIG. 2, semiconductor die 12 is attached to a conductive layer 20M1 of flex circuitry 20 with die attach 12DA. Semiconductor die 12 is electrically connected to conductive layer 20M1 with wire bond(s) 32 from die pads 12P to conductive layer flex pads M1P. Flex pads M1P are depicted in the cross-sectional view of FIG. 2 as rising above layer 20M1 but, as those of skill recognize, these are shown with elevated profile for heuristic purposes and in practice are typically a part of layer 20M1 and would be indistinguishable in this view. Conductive layers of flex circuitry 20 such as, for example, layer 20M1, are typically copper that has been plated with emersion nickel gold or emersion nickel silver or organic surface protection where needed.

Semiconductor die 14 is shown set, at least in part, into flex window FW that projects at least part of the way into flex circuitry 20. A layer of flex circuitry 20 is exposed in flex window FW and, in this embodiment, that exposed layer is a conductive layer identified in FIG. 2 as layer 20M3 although the exposed layer to which semiconductor die is attached need not be conductive, particularly when semiconductor die 14 is electrically connected with wire bonds to a layer different than the exposed layer in flex window FW. In this embodiment, semiconductor die 14 is attached to layer 20M3 with die attach 14DA and is electrically connected to a different conductive layer 20M4 with wire bonds 32 that extend from die pads 14P to flex pads M4P.

Semiconductor die 12 and semiconductor die 14 have contact faces 13 along which are disposed contacts 12P and 14P. In the embodiment shown in FIG. 2, semiconductor die 12 and 14 are oriented so that their respective contact faces are oriented in opposite directions and, in this embodiment, away from flex circuitry 20. As those of skill will recognize, the two die may have their respective contact faces oriented toward each other (e.g., when they are flip-chip devices) or each of the respective contact faces may face in the same direction.

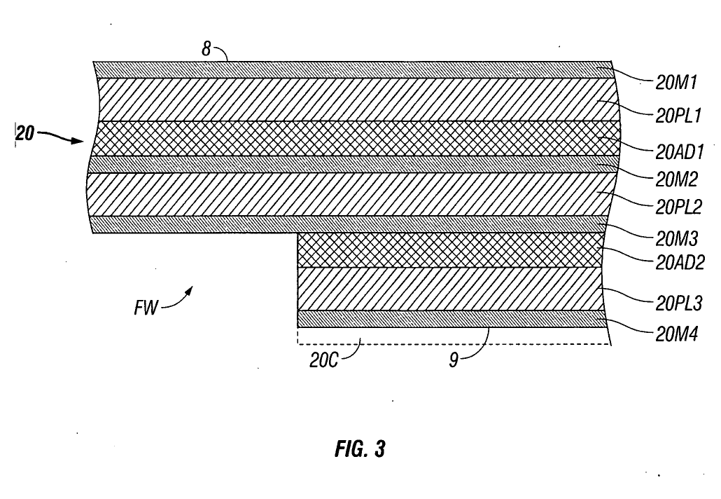

FIG. 3 is a cross-sectional depiction of a preferred flex circuitry that may be employed in a preferred embodiment of the present invention. As illustrated in FIG. 3, flex circuitry 20 is a multi-layer flex circuit that includes in the depiction, four conductive layers 20M1, 20M2, 20M3, and 20M4 although one or more of the conductive layers need not be included in some embodiments. The conductive layers may be identified in an identification scheme as a first conductive layer and plural secondary conductive layers. Each of the aforementioned layers are preferably conductive layers and typically are comprised from metallic materials as more specifically mentioned earlier. Three intermediate layers are identified as layers 20PL1, 20PL2, and 20PL3 and, as those of skill will recognize, the intermediate layers are preferably polyimide. Two adhesive layers are shown and identified as layers 20AD1 and 20AD2. Also shown is optional covercoat 20C to illustrate the optional use of covercoats. Covercoats on flex circuitry are well understood by those of skill in the art and it should be recognized that either or both sides of flex circuitry 20 may have a covercoat although typically, no covercoat is employed. Conductive layers in flex circuitry are well understood in the art and typically comprise a network of connections that allow interconnections between various components to be realized through the conductive layers.

Flex circuitry 20 is comprised preferably of multiple layers and consequently, flex circuitry 20 exhibits, therefore, typically a greater rigidity than flex circuits with only one layer. Even so, encapsulate 16 assists in providing structure for circuit module 10. In alternative construction choices, flex circuitry 20 may be devised from rigid flex.

FIG. 3 illustrates a portion of flex window FW and illustrates the exposure of flex layer 20M3 in window FW although other layers such as a polyimide layer such as 20PL2 may be alternatively exposed through flex window FW.

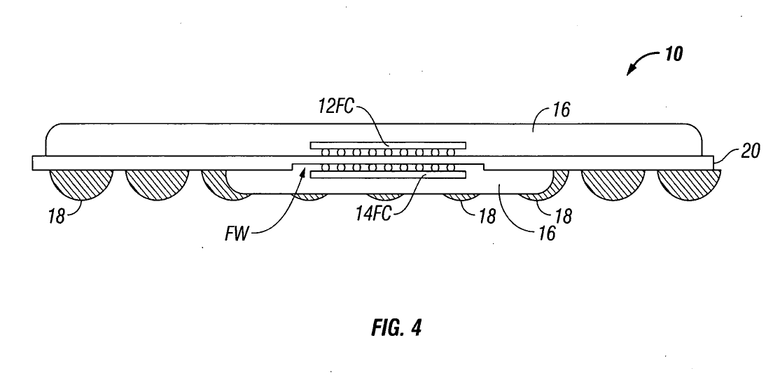

FIG. 4 is a cross-sectional depiction of a circuit module 10 that is an alternative embodiment in accordance with the present invention. The module depicted in FIG. 4 is comprised from two semiconductor die identified as 12FC and 14FC to signify their configuration as being flip-chip. Those of skill are familiar with flip-chip devices. Although flip-chip devices are sometimes identified as being a species of CSP device, here they will be identified as being in the class of semiconductor die.

In the module depicted in FIG. 4, the two flip-chip semiconductor die 12 and 14, respectively, have their respective contact faces oriented toward each other and the flex circuitry. Semiconductor die 14FC is set, at least in part, into flex window FW. Module contacts are shown along flex circuitry 20 and encapsulate 16 is depicted about the respective semiconductor die 12FC and 14FC.

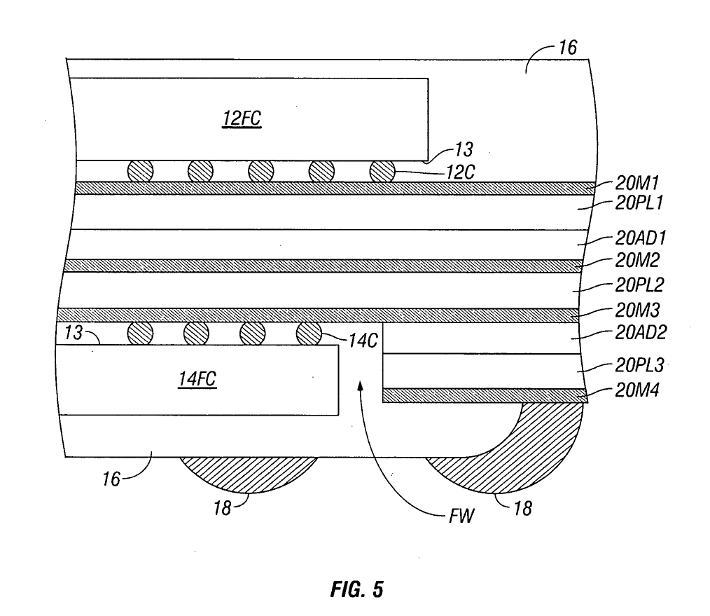

FIG. 5 is an enlarged cross-sectional depiction of a portion of a circuit module in accordance with an alternative embodiment of the present invention in which two semiconductor die that are each flip-chip devices are employed. Semiconductor die 12FC is attached to and electrically connected to conductive layer 20M1 of flex circuitry 20, while semiconductor die 14FC is attached to and connected to layer 20M3 that is exposed in window FW. In this embodiment, semiconductor die 12FC and 14FC are oriented so that their contact faces 13 are oriented toward each other and the flex circuitry.

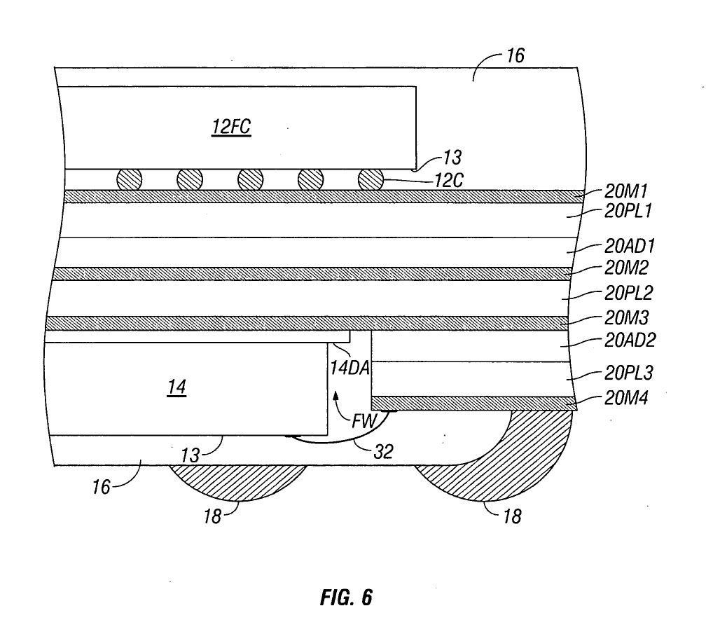

FIG. 6 is an enlarged cross-sectional depiction of a portion of a circuit module in accordance with an alternative embodiment of the present invention in which semiconductor die 12FC which is a flip-chip device, and semiconductor die 14 which is wire bond connected to flex circuitry 20, are combined in a single module. Just as this depiction shows the combination of a flip-chip device as semiconductor die 12FC combined with wire bond connected semiconductor die 14, those of skill in the art understand that semiconductor die 14 may be configured as a flip-chip device while semiconductor die 12 is wire-bonded to flex circuitry 20.

As illustrated, semiconductor die 14 projects into window FW which is accessible from side 9 of flex circuitry 20 and which, in this embodiment, extends at least through layer 20M4 and layer 20PL3. Although attached to layer 20M3 through die attach 14DA, semiconductor die 14 is electrically connected to layer 20M4 through wire bonds 32 that extend between die pads 14P and flex pads 20P of layer 20M2.

In the embodiments of the present invention, preferably, semiconductor die 12 (or 12FC) is a memory circuit, while semiconductor die 14 (or 14FC) is a controller. Typically, the module of the present invention will employ a flash memory circuit as semiconductor die 12 (or 12FC) and a controller circuit as semiconductor die 14 (or 14FC). The present invention may also be employed with circuitry other than or in addition to memory. Other exemplar types of circuitry that may be aggregated in accordance with embodiments of the invention include, just as non-limiting examples, DRAMs, FPGAs, and system stacks that include logic and memory as well as communications or graphics devices. It should also be noted that although not typical, more than two semiconductor die may be disposed in a circuit module in accordance with the invention and it should be understood that the depicted relative lateral orientations of the semiconductor die along the flex circuitry are illustrative and not limiting.

It will be seen by those skilled in the art that many embodiments taking a variety of specific forms and reflecting changes, substitutions, and alternations can be made without departing from the spirit and scope of the invention. Therefore, the described embodiments illustrate but do not restrict the scope of the claims.

1. A flash memory circuit module comprising:
flex circuitry having first and second sides and a window extending partially through the flex circuitry, the flex circuitry having at least a first conductive layer and plural secondary conductive layers;
a first flash memory semiconductor die attached and electrically connected to the first conductive layer of the flex circuitry;
a second semiconductor die that is a controller, the second semiconductor die being disposed at least in part into the window and attached to a selected first one of the plural secondary conductive layers; and
plural module contacts.

2. The flash memory circuit module of claim 1 in which the second semiconductor die is electrically connected to the selected first one of the plural secondary conductive layers.

3. The flash memory circuit module of claim 1 in which the second semiconductor die is electrically connected to a selected second one of the plural secondary conductive layers.

4. The flash memory circuit module of claim 1 in which both the first and the second semiconductor die are surrounded by encapsulate.

5. The flash memory circuit module of claim 3 in which the second semiconductor die is electrically connected to the selected second one of the plural secondary conductive layers with wire bonds.

6. The flash memory circuit module of claim 2 in which the second semiconductor die is a flip-chip device.

7. The flash memory circuit module of claim 1 in which the flex circuitry has three secondary conductive layers and more than one intermediate layer.

8. The flash memory circuit module of claim 3 in which the first semiconductor die is a flip-chip device.

9. The flash memory circuit module of claim 2 in which the first semiconductor die is electrically connected with wire bonds to the first conductive layer of the flex circuitry.

10. The flash memory circuit module of claim 1 in which one of the first or the second semiconductor die is attached to the flex circuitry with die attach.

11. The flash memory circuit module of claim 1 in which the first and second semiconductor die are electrically connected to the flex circuitry with wire bonds.

12. The flash memory circuit module of claim 1 in which a selected one of the plural secondary conductive layers is exposed through the window and the second semiconductor die is attached to the selected one of the plural secondary conductive layers.

13. A circuit module comprising:
flex circuitry having at least first, second, and third layers, at least the first and third layers being conductive, the flex circuitry having a window that projects into the flex circuitry and through which window at least a portion of the second layer is exposed;
a first semiconductor die which has a contact face and said first semiconductor die is attached and electrically connected to the first conductive layer and a second semiconductor die which has a contact face and which second semiconductor die is inserted at least in part into the window of the flex circuitry and attached to the second layer; and
a set of module contacts.

14. The circuit module of claim 13 in which the first semiconductor die is a flash memory circuit and the second semiconductor die is a controller.

15. The circuit module of claim 13 in which the first semiconductor die is a controller and the second semiconductor die is a flash memory circuit.

16. The circuit module of claim 13 in which the first and second semiconductor die are disposed so as to orient their respective contact faces in opposite directions with respect to each other.

17. The circuit module of claim 16 in which the respective contact faces of the first and second semiconductor die face away from the flex circuitry.

18. The circuit module of claim 16 in which the respective contact faces of the first and second semiconductor die face toward each other.

19. The circuit module of claim 13 in which the respective contact faces of the first and second semiconductor die face in the same direction.

20. The circuit module of claim 13 in which the first and second semiconductor die are electrically connected with wire bonds to the first and third layers of the flex circuitry, respectively.

21. The circuit module of claim 13 in which the second layer of the flex circuitry is conductive and the first and second semiconductor die are flip-chip devices and the second semiconductor die is electrically connected to the second layer.

22. The circuit module of claim 13 in which the first and second die are in encapsulate.

23. The circuit module of claim 13 in which the window extends through at least the third conductive layer but not the second conductive layer of the flex circuitry.

24. The circuit module of claim 13 in which adhesive is disposed between at least the first and second layers of the flex circuitry.

25. The circuit module of claim 13 in which the first and second semiconductor die are electrically connected to the flex circuitry with wire bonds.

26. The circuit module of claim 25 in which encapsulate covers the wire bonds.

27. A circuit module comprising:
flex circuitry having first and second sides, the flex circuitry comprising multiple layers including at least first and second conductive layers and the flex circuitry having a window that projects into the flex circuitry;
a flash memory semiconductor die attached and electrically connected to the first conductive layer; and
a second semiconductor die inserted at least in part into the window and attached to and electrically connected to the second conductive layer of the flex circuitry.

28. The circuit module of claim 27 in which the flash memory semiconductor die is electrically connected to one of the first conductive layer of the flex circuitry with wire bonds.

29. The circuit module of claim 28 in which encapsulate covers the wire bonds.

30. The circuit module of claim 27 in which the second semiconductor die is a controller.
